(19) United States
(12) Patent Application Publication
(10) Pub. No.: US 2026/0367195 A1
(43) Pub. Date: Nov. 19, 2026

(54) Quantum Measurement Method and Apparatus

(71) Applicant: Chong Qing University of Technology, Chongqing (CN)

(72) Inventors: Xiaokang Liu, Chongqing (CN); Jianwei Wei, Chongqing (CN); Changliang Wu, Chongqing (CN); Bingnan Zhan, Chongqing (CN); Min Fu, Chongqing (CN)

(21) Appl. No.: 19/133,414

(22) PCT Filed: Dec. 21, 2023
(86) PCT No.: PCT/CN2023/140503

§ 371 Date: May 28, 2025

(30) Foreign Application Priority Data
Jan. 11, 2023 (CN) 202310041537.1

(51) Int. Cl. G01R 33/032

(52) U.S. Cl. CPC G01R 33/032

(57) ABSTRACT

A quantum measurement method and device are provided, which belongs to the field of quantum technology. The method comprises: processing an atomic ensemble to cause magnetic moment of the atomic ensemble to perform uniform circular rotational motion, and obtaining angular velocity of the magnetic moment of the atomic ensemble; arranging a first probing light and a second probing light, wherein the first probing light and the second probing light are used to detect the magnetic moment of the atomic ensemble; obtaining a first time point when the first probing light detects the magnetic moment of the atomic ensemble and a second time point when the second probing light detects the magnetic moment of the atomic ensemble; determining an angle between the first and second probing lights based on the first time point, the second time point, and the angular velocity of the magnetic moment of the atomic ensemble.

### CROSS-REFERENCE TO RELATED APPLICATION

The present application claims priority to Chinese Patent Application No. 202310041537.1 filed in China on Jan. 11, 2023, the entire contents of which are incorporated herein by reference.

### TECHNICAL FIELD

The present application relates to the field of quantum technology, and in particular to a quantum measurement method and device.

### BACKGROUND

Quantum precision measurement is an emerging interdisciplinary field combining quantum mechanics and metrology, representing a highly challenging and internationally significant frontier area of scientific research.

Traditional classical sensing technologies based on microelectronics have gradually approached their physical limits, posing severe challenges to the advancement of precision measurement techniques. New measurement techniques based on quantum effects are beginning to emerge. Quantum precision measurement can achieve various measurements that classical methods cannot accomplish. However, known quantum measurement techniques suffer from low accuracy and fail to meet measurement requirements.

### SUMMARY

An object of the embodiments of the present application is to provide a quantum measurement method and device to address the problem of low accuracy in known quantum measurement techniques.

In a first aspect, an embodiment of the present application provides a quantum measurement method, including:
processing an atomic ensemble to cause magnetic moment of the atomic ensemble to perform uniform circular rotational motion, and obtaining angular velocity of the magnetic moment of the atomic ensemble;
arranging a first probing light and a second probing light, wherein the first probing light and the second probing light are used to detect the magnetic moment of the atomic ensemble;
obtaining a first time point when the first probing light detects the magnetic moment of the atomic ensemble and a second time point when the second probing light detects the magnetic moment of the atomic ensemble;
determining an angle between the first probing light and the second probing light based on the first time point, the second time point, and the angular velocity of the magnetic moment of the atomic ensemble.

Optionally, the processing the atomic ensemble to cause the magnetic moment of the atomic ensemble to perform the uniform circular rotational motion includes:
applying a static magnetic field to the atomic ensemble along a first direction;
applying pump light to the atomic ensemble along the first direction;
applying a radio frequency magnetic field to the atomic ensemble along a second direction and a third direction, to cause the magnetic moment of the atomic ensemble to perform uniform circular rotational motion around the first direction, wherein the second direction is perpendicular to the third direction, and the first direction is perpendicular to both the second direction and the third direction.

Optionally, the determining the angle between the first probing light and the second probing light based on the first time point, the second time point, and the angular velocity of the magnetic moment includes:
determining a target time difference based on the first time point and the second time point;
determining an angle between the first probing light and the second probing light based on the target time difference and the angular velocity of the magnetic moment.

Optionally, a position of the first probing light relative to the atomic ensemble is constant, and a position of the second probing light relative to the first probing light is variable.

In a second aspect, an embodiment of the present application provides a quantum measurement device, including:
an atom processing module, configured for processing an atomic ensemble to cause magnetic moment of the atomic ensemble to perform uniform circular rotational motion, and obtaining angular velocity of the magnetic moment of the atomic ensemble;
a probe light arrangement module, configured for arranging a first probing light and a second probing light, wherein the first probing light and the second probing light are used to detect the magnetic moment of the atomic ensemble;
an obtaining module, configured for obtaining a first time point when the first probing light detects the magnetic moment of the atomic ensemble and a second time point when the second probing light detects the magnetic moment of the atomic ensemble;
a determination module, configured for determining an angle between the first probing light and the second probing light based on the first time point, the second time point, and the angular velocity of the magnetic moment of the atomic ensemble.

In a third aspect, an embodiment of the present application provides another quantum measurement device, including an atom processing component, a first probe and a second probe; wherein the atom processing component includes an gas chamber, a heating structure and a uniform rotation processing component; an atomic ensemble is arranged in the gas chamber; the gas chamber is filled with an inert gas; the gas chamber is arranged in the heating structure; the uniform rotation processing component is arranged outside the heating structure, and is configured for applying a magnetic field and an optical field to the atomic ensemble to cause magnetic moment of the atomic ensemble to perform uniform circular rotational motion; the first probe and the second probe are arranged outside the heating structure; a light outlet of the first probe faces the atomic ensemble, a light outlet of the second probe faces the atomic ensemble, and the second probe and the first probe are circumferentially arranged at an interval around the atomic ensemble.

Optionally, the uniform rotation processing component includes a laser, a first magnetic field coil, a second magnetic field coil and a third magnetic field coil; the laser, the first magnetic field coil, the second magnetic field coil and the third magnetic field coil are all arranged outside the heating structure; a coil plane of the first magnetic field coil is perpendicular to a first direction and arranged facing the atomic ensemble; a light outlet of the laser is parallel to the first direction and arranged facing the atomic ensemble; a coil plane of the second magnetic field coil is perpendicular to a second direction and arranged facing the atomic ensemble; a coil plane of the third magnetic field coil is perpendicular to a third direction and arranged facing the atomic ensemble; the second direction is perpendicular to the third direction; and the first direction is perpendicular to both the second direction and the third direction.

Optionally, the atom processing component further includes a magnetic field shielding tube; the gas chamber, the heating structure, the first magnetic field coil, the second magnetic field coil and the third magnetic field coil are all arranged inside the magnetic field shielding tube; and the laser, the first probe and the second probe are all arranged outside the magnetic field shielding tube.

Optionally, the atom processing component further includes a first light processing member, a second light processing member, and a third light processing member;
the first light processing member is arranged between the light outlet of the first probe and the magnetic field shielding tube, and is configured for adjusting a first probing light emitted by the first probe;
the second light processing member is arranged between the light outlet of the second probe and the magnetic field shielding tube, and is configured for adjusting a second probing light emitted by the second probe;
the third light processing member is arranged between the light outlet of the laser and the magnetic field shielding tube, and is configured for adjusting pump light emitted by the laser.

Optionally, the first probe is a fixed probe, and the second probe is a movable probe.

In the embodiments of the present application, the atomic spin is utilized to construct a highly uniform motion, that is, it causes the magnetic moment of the atomic ensemble to perform uniform circular rotational motion as a time reference, forming a “time grating”. This approach abandons the traditional “spatial grating” structure, eliminating the need for highly precise periodic grating lines as a displacement measurement reference, making it more convenient to use. By accurately obtaining the first and second time points, the angular displacement of the atomic ensemble can be determined, thereby determining the angle between the first probing light and the second probing light, and significantly improving the accuracy of the quantum measurement.

### BRIEF DESCRIPTION OF THE DRAWINGS

FIG. 1 is a schematic flowchart of the quantum measurement method provided by an embodiment of the present application;

FIG. 2 is a schematic diagram of the motion of an atomic ensemble in its natural state;

FIG. 3 is a schematic diagram of the motion of an atomic ensemble under the influence of a static magnetic field;

FIG. 4 is a schematic diagram of the motion of an atomic ensemble under the influence of a static magnetic field and pump light;

FIG. 5 is a schematic diagram of the motion of an atomic ensemble under the influence of a static magnetic field, pump light, and an Radio Frequency (RF) magnetic field in one direction;

FIG. 6 is a schematic diagram of the motion of an atomic ensemble under the influence of a static magnetic field, pump light, and RF magnetic fields in two directions;

FIG. 7 is a schematic diagram of the relationship between magnetization intensities in two coordinate systems;

FIG. 8 (a) is a schematic diagram of the positional relationship between an atomic ensemble under the influence of a static magnetic field, pump light, and RF magnetic fields in two directions, and the first probing light and the second probing light;

FIG. 8 (b) is a schematic diagram illustrating a principle of determining an angle between a first probing light and a second probing light based on a first time point, a second time point, and angular velocity of the magnetic moment of the atomic ensemble;

FIG. 9 is a schematic structural diagram of a quantum measurement device provided by an embodiment of the present application;

FIG. 10 is another schematic structural diagram of a quantum measurement device provided by an embodiment of the present application.

### DETAILED DESCRIPTION

The technical solutions in the embodiments of the present application will be clearly and completely described below with reference to the accompanying drawings. Obviously, the described embodiments are only a part of the embodiments of the present application, not all of them. Based on the embodiments of the present application, all other embodiments obtained by those of ordinary skill in the art without creative effort shall also fall within the protection scope of the present application.

The terms “first,” “second,” etc., in the description and claims of the present application are used to distinguish similar objects and are not intended to describe a specific order or sequence. It should be understood that such terms are interchangeable under appropriate circumstances, so that the embodiments of the present application can be implemented in orders other than those illustrated or described herein. Additionally, the objects distinguished by “first,” “second,” etc., are generally of the same type, and the number of such objects is not limited. For example, a first object may be one or more. Furthermore, “and/or” in the description and claims indicates at least one of the connected objects, and the character “/” generally indicates an “or” relationship between the associated objects.

The quantum measurement method provided in the embodiment of the present application is described in detail below through specific embodiments and their application scenarios in conjunction with the accompanying drawings.

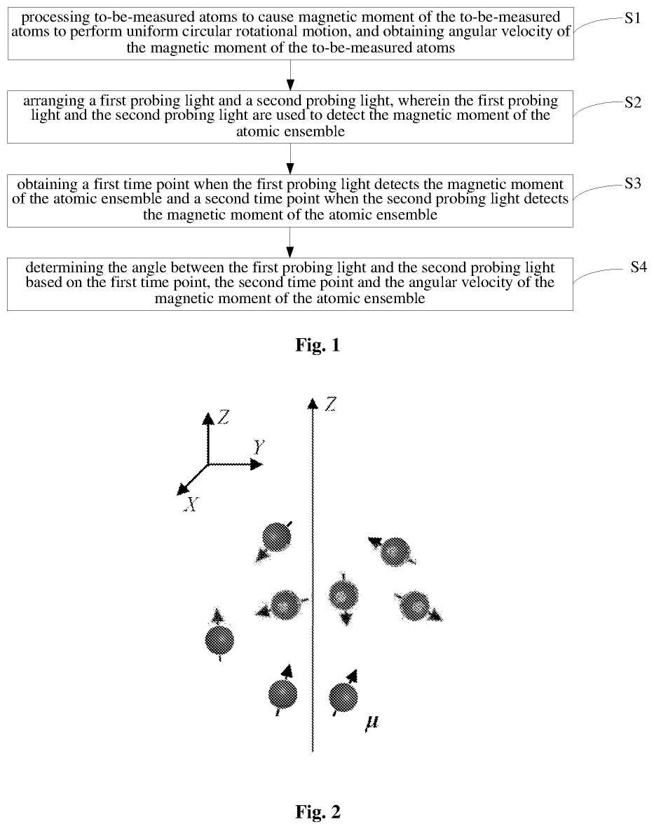

As shown in FIG. 1, the quantum measurement method provided in the embodiment of the present application includes the following steps.

Step S1: processing an atomic ensemble to cause magnetic moment of the atomic ensemble to perform uniform circular rotational motion, and obtaining angular velocity of the magnetic moment of the atomic ensemble.

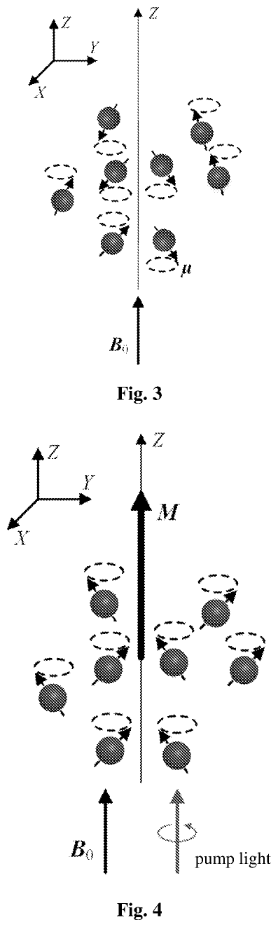

Atomic spin is an intrinsic property of atoms. Atomic spin includes nuclear spin and electron spin, and is a kind of “natural” motion. Atomic spin has angular momentum and generates spin magnetic moment u. However, as shown in FIG. 2, in the natural state, the direction of atomic spin is chaotic. In this case, it is impossible to use the atomic spin phenomenon for measurement. Even if the atomic spin magnetic moment is measured by an instrument, the resulting angular displacement of the atom is inaccurate.

In the embodiments of the present application, the effect of the optical field and the magnetic field on atom is utilized. For example, when the atom is affected by a static magnetic field, the nucleus of the atom will be affected by the torque, and the motion of the magnetic moment of the atom will change. For example, when the atom is affected by the optical field, a unidirectional polarization of the magnetic moment of the atom will be formed, and the motion of the magnetic moment of the atom will also be affected. Therefore, a suitable optical field and magnetic field are applied to the atomic ensemble to cause magnetic moment of the atomic ensemble to perform uniform circular rotational motion. It should be noted that when the magnetic moment of the atomic ensemble performs uniform circular rotational motion, the magnetic moment of the atomic ensemble is measured, and the accurate angular displacement of the atomic ensemble is obtained based on the angular velocity of the magnetic moment of the atomic ensemble.

Step S2, arranging a first probing light and a second probing light, wherein the first probing light and the second probing light are used to detect the magnetic moment of the atomic ensemble.

It should be noted that the first probing light and the second probing light can be linearly polarized light, the connecting line between the first probing light and the atomic ensemble and the connecting line between the second probing light and the atomic ensemble are located in the same plane, and there is a certain angle between the connecting line between the first probing light and the atomic ensemble and the connecting line between the second probing light and the atomic ensemble, that is, the first probing light and the second probing light are emitted to the atomic ensemble from different directions. When the magnetic moment of the atomic ensemble performs uniform circular rotational motion, it forms a rotating magnetic field. When the rotating magnetic field moves to the position of the first probing light or the second probing light, the optical signal of the first probing light or the second probing light will change.

Step S3, obtaining a first time point when the first probing light detects the magnetic moment of the atomic ensemble and a second time point when the second probing light detects the magnetic moment of the atomic ensemble.

It can be understood that when the first probing light detects the rotating magnetic field formed by the magnetic moment, the time information of this time point is recorded, i.e., the first time point. When the second probing light detects the rotating magnetic field formed by the magnetic moment of the atomic ensemble, the time information of this time point is recorded, i.e., the second time point.

Step S4, determining the angle between the first probing light and the second probing light based on the first time point, the second time point and the angular velocity of the magnetic moment of the atomic ensemble.

According to the first time point, the second time point and the angular velocity of the magnetic moment of the atomic ensemble, the angular displacement of the atomic ensemble is determined. It can be understood that the angular displacement of the atomic ensemble is consistent with the angle between the first probing light and the second probing light, so the angle between the first probing light and the second probing light can be obtained. The angular velocity of the magnetic moment of the atomic ensemble can be obtained by real-time detection of the period of the signal of the first probing light.

Therefore, in the quantum measurement method of the embodiments of the present application, the atomic spin is utilized to construct a highly uniform motion, that is, it causes the magnetic moment of the atomic ensemble to perform uniform circular rotational motion as a time reference, forming a “time grating”. This approach abandons the traditional “spatial grating” structure, eliminating the need for highly precise periodic grating lines as a displacement measurement reference, making it more convenient to use. By accurately obtaining the first and second time points, the angular displacement of the atomic ensemble can be determined, thereby determining the angle between the first probing light and the second probing light, and significantly improving the accuracy of the quantum measurement.

In the embodiments of the present application, the quantum measurement method can be applied to high-precision measurement. For example, when it is necessary to measure displacement of an object, a first probing light is arranged at a starting point of the object, and a second probing light is arranged at an end point of the object. The atomic ensemble with the magnetic moment capable of performing uniform circular rotational motion in the above-mentioned quantum measurement method is used to obtain the angle between the first probing light and the second probing light, and the displacement of the object can be obtained through further calculation.

Optionally, the step S1 of processing the atomic ensemble to cause the magnetic moment of the atomic ensemble to perform uniform circular rotational motion, includes the following.

Applying a static magnetic field to the atomic ensemble along a first direction,

The nuclear spin of each atom in the atomic ensemble has angular momentum and generates a spin magnetic moment μ. As shown in FIG. 3, a static magnetic field B₀ is applied along the first direction, i.e., the Z-axis direction shown in FIG. 3. Since a direction of the spin magnetic moment μ of the nucleus of the atom is inconsistent with the direction of the static magnetic field B₀, the nucleus of the atom is subjected to a torque perpendicular to the plane formed by μ and B₀, causing the nucleus of the atom to perform Larmor precession around the direction of the static magnetic field B₀.

Applying pump light to the atomic ensemble along the first direction.

As shown in FIG. 4, the pump light is applied along the first direction, i.e., the Z-axis direction shown in FIG. 4. The pump light may be circularly polarized pump light. The atom is polarized by the pump light. The atom may be alkali metal atom. Based on the selection rules of angular momentum conservation, the atomic energy level is concentrated to a specific energy level, and the orientation of the electron spin magnetic moment is polarized from any direction to a specific direction, thereby forming a unidirectional polarization of the atomic magnetic moment. Subsequently, the atomic ensemble undergoes a spin exchange collision with the inert gas working medium, and obtains a macroscopic nuclear spin magnetic moment M in the Z-axis direction. The macroscopic nuclear spin magnetic moment M can also be called magnetization intensity. At this time, the magnetic moment of each atom in the atomic ensemble precesses along the Z-axis at the Larmor frequency.

A radio frequency magnetic field is applied to the atomic ensemble along a second direction and a third direction to cause magnetic moment of the atomic ensemble to perform uniform circular rotational motion around the first direction, wherein the second direction is perpendicular to the third direction, and the first direction is perpendicular to both the second direction and the third direction.

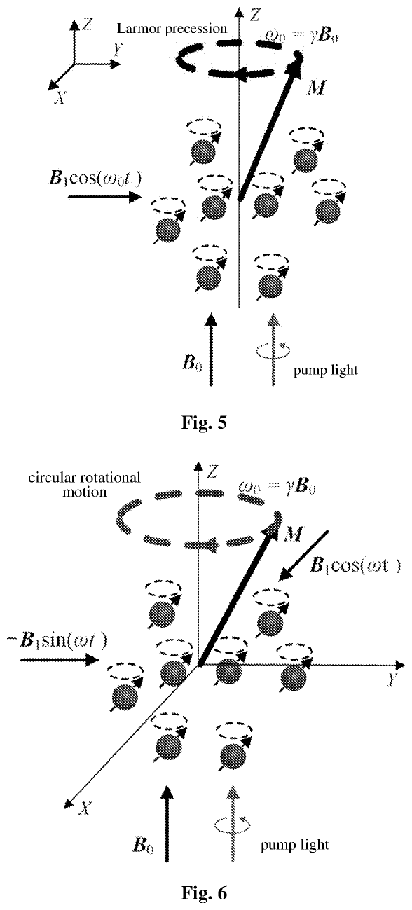

In FIG. 5, an oscillating magnetic field B₁ cos (ω₀t) equal to the precession frequency of the nuclei of the atoms in the atomic ensemble is applied along the second direction, i.e., the Y-axis direction perpendicular to the Z-axis direction as shown in FIG. 5, to put the working medium of the atomic ensemble in a state of resonance between Zeeman sub-levels, that is, to make the precession frequency of the spin magnetic moment of the atomic ensemble resonate with the radio frequency. This makes the precession phase of the nuclear spin magnetic moment of the atomic ensemble coherent in the XY plane, maximizes the macroscopic nuclear spin magnetic moment M, and the macroscopic nuclear spin magnetic moment undergoes Larmor precession under the action of the torque M×B₀, with an angular velocity of precession ω₀=γB₀, where γ is the gyromagnetic ratio of the atoms in the atomic ensemble, which is a characteristic constant determined by the type of nuclei of the atoms in the atomic ensemble. The applied radio frequency magnetic field B₁ cos (ω₀t) is a linearly polarized magnetic field, which can be decomposed into two circularly polarized magnetic fields with opposite rotation directions in the XY plane and rotating around the Z axis. A magnetic field in the opposite direction of the magnetic moment rotation will not have any effect, and only a magnetic field in the same direction as the precession of the magnetic moment will resonate with the precession of the magnetic moment of the atomic ensemble. Due to the linear polarization magnetic field in a single direction, the precession signal generated by the radio frequency can only be measured once in one direction during actual measurement and detection. Therefore, when there is only a linear polarization magnetic field in one direction, it is impossible to measure the detection signal in two directions at the same time in the XY plane.

As shown in FIG. 6, in order to realize the simultaneous measurement of detection signals in any two directions in the XY plane, and thereby obtain the phase difference of the atomic ensemble precessing to different positions, oscillating magnetic fields B₁ cos (ω₀t) and −B₁ sin (ω₀t) with a frequency being equal to the nuclear precession frequency of the atoms in the atomic ensemble are applied in the third direction perpendicular to the Z axis, that is, the X axis direction and the second direction, that is, the Y axis direction, respectively. The macroscopic nuclear spin magnetic moment of the atomic ensemble still produces clockwise (as shown in FIG. 6, looking down along the Z axis) Larmor precession under the action of the torque M×B₀. At this time, the magnetic fields B₁ cos (ω₀t)\vec{X} and −B₁ sin (ω₀t)\vec{Y} in the XY plane both rotate in the clockwise direction, forming a resonance with the Larmor precession. At this time, the nuclear spin magnetic moment M of the atomic ensemble is affected by B₁ cos (ω₀t)\vec{X} and −B₁ sin (ω₀t)\vec{Y}, and the M rotates in a uniform circular rotational motion with an angular velocity ω₀ around the center point of the XYZ space coordinate system, and rotates at an angular velocity ω₀=γB₀. At this time, the linearly polarized magnetic fields in the two directions applied in the XY plane constitute a physically actual uniform circular rotating magnetic field. This provides the physical basis for the simultaneous measurement of two detection signals in any direction in the XY plane when actually measuring the detection signal. The specific principles are as follows.

As shown in FIG. 6, when the static magnetic field B₀ and the pump light are applied in the Z-axis direction, the electron spin magnetic moment is polarized by the pump light, and the atomic ensembles in space will generate a macroscopic nuclear spin magnetic moment M along the Z-axis direction, also known as magnetization intensity. Although each of the atoms precesses along the Z-axis at the Larmor frequency at this time, their phases are not uniform, so they do not have polarization vector components in the XY plane, M_{L}=0. In order to obtain non-zero M_{L} uniform circular rotational motion (a direction of the rotation is consistent with the direction of the Larmor precession) as the uniform rotation reference system of the time grating, it is necessary to make the atomic spin magnetic moment coherent to form a macroscopic precession magnetization intensity M. A radio frequency magnetic field of the same amplitude (whose frequency is equal to the Larmor precession frequency of the inert gas) is added in each of the X-axis direction and the Y-axis direction, and its direction is orthogonal to the Z axis, with magnitudes of −B₁ sin (ω₀t) and B₁ cos (ω₀t), respectively. Because the nuclear magnetic resonance makes the atomic precession phase coherent and synchronized, it finally has a component M_{L} in the XY plane.

Under the effect of the radio frequency magnetic field, the precession phase of the nuclear magnetic moment tends to be in phase from random distribution, so that the atomic nucleus system produces transverse and longitudinal magnetization intensity. If the radio frequency magnetic field is removed, it can be found that the magnetization intensity will gradually disappear over time. This phenomenon is called spin relaxation. The two time constants T1 and T2 are used to describe the relaxation process. The longitudinal spin relaxation time T1 represents the time required for the Z component M_{Z} of M to return to its equilibrium state along the Z axis. The transverse spin relaxation time T2 represents the time it takes for M_{X} or M_{Y} to return to zero. The relaxation process can be expressed as:

$$\{ \begin{matrix}\frac{d {M}_{x}}{d t} = - \frac{{M}_{x}}{{T}_{2}} \\ \frac{d {M}_{y}}{d t} = - \frac{{M}_{y}}{{T}_{2}} \\ \frac{d {M}_{z}}{d t} = \frac{{M}_{z} - {M}_{0}}{{T}_{1}} \\ \frac{d {M}_{L}}{d t} = - \frac{{M}_{L}}{{T}_{2}}\end{matrix} \qquad ( 1 )$$

M_{X} represents X component of M, M_{Y} represents the Y component of M, M_{Z} represents Z component of M, T1 represents M_{Z} the time required for the Z component of M to return to its equilibrium state along the Z axis, T2 represents the time it takes M_{X} or M_{Y} to return to zero. M_{L} represents the component formed in the XY plane by adding an RF magnetic field with the same amplitude in the X-axis direction and the Y-axis direction, which induces nuclear magnetic resonance in the atomic ensemble. M₀ represents the equilibrium magnetization intensity, and dt represents the derivative with respect to time. From formula (1), it can be obtained:

$$\{ \begin{matrix}{M}_{Z} = {M}_{0} ( 1 - {e}^{- \frac{t}{{T}_{1}}} ) \\ {M}_{L} = {M}_{Lmax} {e}^{- \frac{t}{{T}_{2}}}\end{matrix} \qquad ( 2 )$$

M_{Lmax}represents the maximum value of M_{L}. The Bloch equation represents a model of the interaction between the magnetic field and M, where M is obtained by the superposition of the external field and spin relaxation, that is,

$$\frac{d M}{dt} = γ ( M \times B ) + spin$$

relaxation, where γ represents the magnetic gyroscopic ratio. It can be obtained:

$$\{ \begin{matrix}\frac{d {M}_{x}}{d t} = γ ( {M}_{y} {B}_{z} - {M}_{z} {B}_{y} ) - \frac{{M}_{x}}{{T}_{2}} \\ \frac{d {M}_{y}}{d t} = γ ( {M}_{z} {B}_{x} - {M}_{x} {B}_{z} ) - \frac{{M}_{y}}{{T}_{2}} \\ \frac{d {M}_{z}}{d t} = γ ( {M}_{x} {B}_{y} - {M}_{y} {B}_{x} ) - \frac{{M}_{z} - {M}_{0}}{{T}_{1}}\end{matrix} \qquad ( 3 )$$

B_{Z} represents the component of the magnetic field B on the Z axis, Bₓ represents the component of the magnetic field B on the X axis, and B_{y} represents the component of the magnetic field B on the Y axis. The magnetic field B can be expressed as B=B₁ cos (ωt)\vec{x}−B₁ sin (ωt)\vec{y}+B₀\vec{z}, where B₀ is the static magnetic field intensity, B₁ cos (ωt)\vec{x} represents the radio frequency magnetic field intensity along the X axis, B₁ sin (ωt)\vec{y} represents the radio frequency magnetic field intensity along the Y axis, where B₀ is much greater than B₁. Considering the two vectors X and Y respectively, the clockwise vector component of the Y component is:

\vec{B_{y1}}=−1/2B₁ sin(ωt)\vec{y}+1/2B₁ cos(ωt)\vec{x}

The counterclockwise component of the Y component is:

\vec{B_{y2}}=−1/2B₁ sin(ωt)\vec{y}−1/2B₁ cos(ωt)\vec{x}

The component of the clockwise vector of the X component is:

\vec{Bₓ₁}=1/2B₁ cos(ωt)\vec{x}−1/2B₁ sin(ωt)\vec{y}

The component of the counterclockwise vector of the X component is:

\vec{Bₓ₂}=1/2B₁ cos(ωt)\vec{x}+1/2B₁ sin(ωt)\vec{y}

Since the atomic Larmor precession is a clockwise rotation, the RF magnetic field is effective only when the clockwise direction is consistent with the precession direction, so only the clockwise vector component of the RF magnetic field and the part of B_{L}=B₁ cos (ωt)\vec{x}−B₁ sin (ωt)\vec{y} are effective in M_{L} the rotation. At this time, equation (3) can be written as:

$$\{ \begin{matrix}\frac{d {M}_{x}}{d t} = γ [ {M}_{y} {B}_{z} + {M}_{z} {B}_{1} sin ω t ] - \frac{{M}_{x}}{{T}_{2}} \\ \frac{d {M}_{y}}{d t} = γ [ {M}_{z} {B}_{1} cos ω t - {M}_{x} {B}_{z} ] - \frac{{M}_{y}}{{T}_{2}} \\ \frac{d {M}_{z}}{d t} = γ [ - {M}_{x} {B}_{1} sin ω t - {M}_{y} {B}_{1} cos ω t ] - \frac{{M}_{z} - {M}_{0}}{{T}_{1}}\end{matrix} \qquad ( 4 )$$

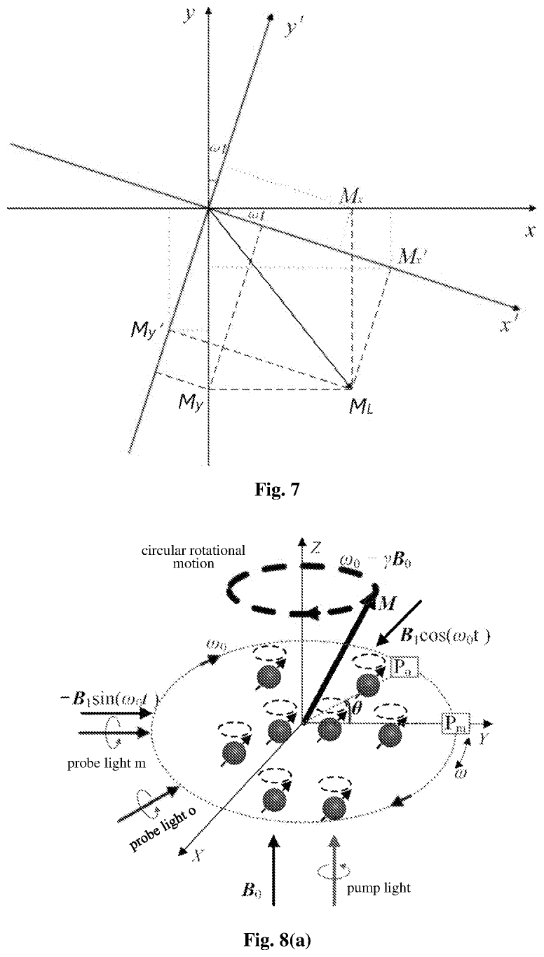

As shown in FIG. 7, a rotation coordinate system x′, y′, Mₓ′ and M_{y}′ around the Z axis at ω is established with constant magnitude and direction, and thus it obtains Mₓ, M_{y}, as well as the conversion expressions between Mₓ′ and M_{y}′, as follows:

$$\{ \begin{matrix}{M}_{x}^{′} = {M}_{x} cos ω t - {M}_{y} sin ω t \\ {M}_{y}^{′} = - ( {M}_{x} sin ω t + {M}_{y} cos ω t )\end{matrix} \qquad ( 5.1 )$$

$$\{ \begin{matrix}{M}_{x} = {M}_{x}^{′} cos ω t - {M}_{y}^{′} sin ω t \\ {M}_{y} = - ( {M}_{x}^{′} sin ω t + {M}_{y}^{′} cos ω t )\end{matrix} \qquad ( 5.2 )$$

Substituting equation (5.1) and equation (5.2) into equation (4), it can obtain:

$$\{ \begin{matrix}\begin{matrix}\frac{{dM}_{x}^{′}}{dt} cos ω t - \frac{{dM}_{y}^{′}}{dt} sin ω t - ω ( {M}_{x}^{′} sin ω t + {M}_{y}^{′} cos ω t ) = \\ γ [ {M}_{y} {B}_{z} + {M}_{z} {B}_{1} sin ω t ] - \frac{{M}_{x}}{{T}_{2}}\end{matrix} ( 6 ) \\ \begin{matrix}- [ \frac{{dM}_{x}^{′}}{dt} sin ω t + \frac{{dM}_{y}^{′}}{dt} cos ω t + ω ( {M}_{x}^{′} cos ω t - {M}_{y}^{′} sin ω t ) ] = \\ γ [ {M}_{z} {B}_{1} cos ω t - {M}_{x} {B}_{z} ] - \frac{{M}_{y}}{{T}_{2}}\end{matrix} ( 7 ) \\ \begin{matrix}\begin{matrix}\frac{{dM}_{z}}{dt} = [ - ( {M}_{x}^{′} cos ( ω t ) - {M}_{y}^{′} sin ω t ) {B}_{1} sin ω t + \\ ( {M}_{x}^{′} sin ω t + {M}_{y}^{′} cos ω t ) {B}_{1} cos ω t ] - \frac{{M}_{z} - {M}_{0}}{{T}_{1}} =\end{matrix} \\ γ {B}_{1} {M}_{y}^{′} - \frac{{M}_{z} - {M}_{0}}{{T}_{1}}\end{matrix} ( 8 )\end{matrix}$$

Subtracting equation (7)×sin (ωt) from equation (6)×cos (ωt) to obtain equation (9), subtracting equation (7)×cos (ωt) from equation (6)×sin (ωt) to obtain equation (10), and simplifying equation (8) to obtain equation (11), as follows:

$$\{ \begin{matrix}\frac{{dM}_{x}^{′}}{d t} - ( ω - {ω}_{0} ) {M}_{y}^{′} + \frac{{M}_{x}^{′}}{{T}_{2}} = 0 ( 9 ) \\ \frac{{dM}_{y}^{′}}{d t} + ( ω - {ω}_{0} ) {M}_{x}^{′} + γ {B}_{1} {M}_{z} + \frac{{M}_{x}^{′}}{{T}_{2}} = 0 ( 10 ) \\ \frac{d {M}_{z}}{d t} - γ {B}_{1} {M}_{y}^{′} - \frac{{M}_{z} - {M}_{0}}{{T}_{1}} = 0 ( 11 )\end{matrix}$$

The RF magnetic fields Bₓ, B_{y} and M are in relaxation equilibrium, Mₓ′, M_{y}′, and M_{z} are constants, and then

$$\frac{{dM}_{x}^{′}}{d t} = \frac{{dM}_{y}^{′}}{d t} = \frac{d {M}_{z}}{d t} = 0 ,$$

substituting into equations (9), (10), and (11), it can obtain:

$$\{ \begin{matrix}{M}_{x}^{′} = {M}_{0} \frac{γ {B}_{1} {T}_{2}^{2} ( {ω}_{0} - ω )}{1 + {{T}_{2}^{2} ( {ω}_{0} - ω )}^{2} + {γ}^{2} {B}_{1}^{2} {T}_{1} {T}_{2}} ( 12 ) \\ {M}_{y}^{′} = {M}_{0} \frac{γ {B}_{1} {T}_{2}}{1 + {{T}_{2}^{2} ( {ω}_{0} - ω )}^{2} + {γ}^{2} {B}_{1}^{2} {T}_{1} {T}_{2}} ( 13 ) \\ {M}_{z} = {M}_{0} \frac{1 + {{T}_{2}^{2} ( {ω}_{0} - ω )}^{2}}{1 + {{T}_{2}^{2} ( {ω}_{0} - ω )}^{2} + {γ}^{2} {B}_{1}^{2} {T}_{1} {T}_{2}} ( 14 )\end{matrix}$$

Substituting equation (6.2) into equations (12) and (13), we can obtain:

$$\{ \begin{matrix}{M}_{x} = γ {T}_{2} {M}_{0} \frac{{T}_{2} ( {ω}_{0} - ω ) {B}_{1} cos ω t + {B}_{1} sin ω t}{1 + {{T}_{2}^{2} ( {ω}_{0} - ω )}^{2} + {γ}^{2} {B}_{1}^{2} {T}_{1} {T}_{2}} ( 15 ) \\ {M}_{y} = γ {T}_{2} {M}_{0} \frac{{B}_{1} cos ω t - {T}_{2} ( {ω}_{0} - ω ) {B}_{1} sin ω t}{1 + {{T}_{2}^{2} ( {ω}_{0} - ω )}^{2} + {γ}^{2} {B}_{1}^{2} {T}_{1} {T}_{2}} ( 16 )\end{matrix}$$

If ω=ω₀, that is, when the frequency of the applied RF magnetic field is equal to the Larmor precession frequency, ω−ω₀=0, substituting into equations (14), (15), and (16), it obtains:

$$\{ \begin{matrix}{M}_{x} = \frac{γ {T}_{2} {B}_{1} {M}_{0}}{1 + {γ}^{2} {B}_{1}^{2} {T}_{1} {T}_{2}} sin {ω}_{0} t ( 17 ) \\ {M}_{y} = \frac{γ {T}_{2} {B}_{1} {M}_{0}}{1 + {γ}^{2} {B}_{1}^{2} {T}_{1} {T}_{2}} cos {ω}_{0} t ( 18 ) \\ {M}_{z} = \frac{{M}_{0}}{1 + {γ}^{2} {B}_{1}^{2} {T}_{1} {T}_{2}} ( 19 )\end{matrix}$$

As mentioned above, when it reaches a resonant stable state under the effect of the steady magnetic field and the radio frequency magnetic field, the system generates magnetization. The component of the magnetization intensity in the Z-axis direction remains unchanged, and the component of the magnetization intensity in the XY plane can be expressed as:

$${M}_{L} = {( {M}_{x}^{2} + {M}_{y}^{2} )}^{1 / 2} = \frac{γ {T}_{2} {B}_{1} {M}_{0}}{1 + {γ}^{2} {B}_{1}^{2} {T}_{1} {T}_{2}} \qquad ( 20 )$$

Its value remains unchanged and it rotates around the Z axis at an angular velocity ω₀. That is, under the effect of the rotating magnetic field, the magnetic moment M forms an angle relative to the Z axis and rotates around the Z axis at an angular velocity ω₀ in a uniform circular rotational motion in the XY plane.

When two coordinate systems that are moving at a uniform speed observe each other, the position difference (displacement) on one coordinate system is expressed as the time difference observed on the other coordinate system. By applying a static magnetic field, an optical field, and a radio frequency magnetic field to the atomic ensemble, the magnetic moment of the atomic ensemble is made to rotate in a uniform circular motion. On this basis, the position difference (displacement) of the atomic ensemble can be converted into a time difference, thereby realizing the conversion of the measurement reference from equal division of space to equal division of time. In addition, the uniformity of the atomic ensemble directly determines the measurement accuracy, and high uniformity means high accuracy. Therefore, through the above steps, the magnetic moment of the atomic ensemble is caused to rotate in a uniform circular motion, thereby ensuring the accuracy of the quantum measurement method provided in the embodiments of the present application.

Optionally, in step S4, the determining the angle between the first probing light and the second probing light based on the first time point, the second time point and the angular velocity of the magnetic moment, includes:
determining a target time difference based on the first time point and the second time point;
determining, based on the target time difference and the angular velocity of the magnetic moment, an angle between the first probing light and the second probing light.

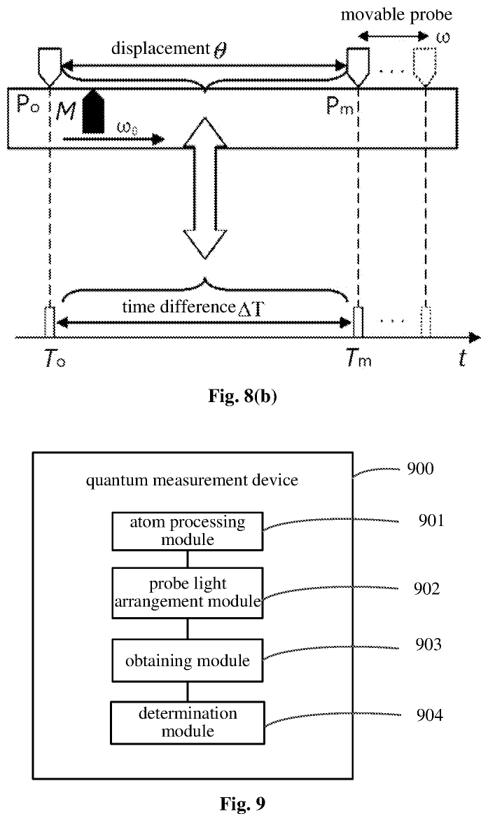

As shown in FIG. 8 (a), the nuclear spin magnetic moment M of the atomic ensemble rotates in a uniform circular motion at an angular frequency ω₀ around the center O of the XYZ spatial coordinate system. When the first probing light detects the magnetic moment of the atomic ensemble, the first time point is recorded as T_{O}, and when the second probing light detects the magnetic moment of the atomic ensemble, the second time point is recorded as Tₘ. The time difference ΔT=Tₘ−T_{O} can be obtained based on the first time point and the second time point, and the angle ϑ=ω₀×ΔT between the first probing light and the second probing light can be obtained based on the “time grating”. The angular velocity ω₀ of the precession of the macroscopic nuclear spin magnetic moment of the atomic ensemble can be obtained by real-time detection of the period T₁ of the signal of the first probing light, and therefore the angle between the first probing light and the second probing light is ϑ=ω₀×ΔT=(2π/T₁)ΔT. In this way, the angle measurement is converted into the measurement of the time difference, without relying on the extremely high-precision equiperiodic grating line as the displacement measurement reference, which offers significant technical advantages and ensures measurement accuracy of the structure.

Optionally, the position of the first probing light relative to the atomic ensemble remains unchanged, and a position of the second probing light relative to the first probing light is variable. As shown in FIG. 8 (b), the first probing light is emitted by the fixed probe P_{O}, and its position does not change, and the second probing light is emitted by the movable probe Pₘ, and its displacement can be changed. Since the position of the movable probe is variable, the second probing light can be sent to the center point O at any position in the XY plane. It can be understood that the angular displacement between the first probing light and the second probing light at any position in the XY plane can be detected, which expands the scope of application of the quantum measurement method of the embodiments of the present application.

Preferably, the movable probe can rotate around the center point O at any speed in the XY plane, and the position between the movable probe and the fixed probe can be changed without manual operation, making the quantum measurement method of the embodiments of the present application more convenient.

For example, when it is necessary to measure the angular displacement of an object performing circular motion, a fixed probe is arranged at the starting point of the object, that is, a first probing light is arranged, and a movable probe is arranged on the object, so that the movable probe moves with the object, that is, the position of the second probing light changes with the change of the object position, and the angular displacement between the fixed probe and the movable probe is obtained by using the atomic ensemble with a magnetic moment capable of performing the uniform circular rotational motion in the above-mentioned quantum measurement method, thereby obtaining the angular displacement of the rotation of the object.

The quantum measurement method provided in the embodiments of the present application can be performed by a quantum measurement device. In the embodiments of the present application, a quantum measurement device performing the quantum measurement method is taken as an example, and the quantum measurement device 900 provided by the embodiments of the present application is described in conjunction with FIG. 9. The device includes:
an atom processing module 901, configured for processing the atomic ensemble to cause the magnetic moment of the atomic ensemble to perform uniform circular rotational motion and obtain the angular velocity of the magnetic moment of the atomic ensemble;
a probe light arrangement module 902, configured for arranging a first probing light and a second probing light, wherein the first probing light and the second probing light are configured to detect the magnetic moment of the atomic ensemble;
an obtaining module 903, configured for obtaining a first time point when the first probing light detects the magnetic moment of the atomic ensemble and a second time point when the second probing light detects the magnetic moment of the atomic ensemble;
a determination module 904, configured for determining the angle between the first probing light and the second probing light based on the first time point, the second time point and the angular velocity of the magnetic moment of the atomic ensemble.

Optionally, the atom processing module 901 is further configured for:
applying a static magnetic field to the atomic ensemble along a first direction;
applying pump light to the atomic ensemble along the first direction;
applying a radio frequency magnetic field to the atomic ensemble along a second direction and a third direction to cause magnetic moment of the atomic ensemble to perform uniform circular rotational motion around the first direction, wherein the second direction is perpendicular to the third direction, and the first direction is perpendicular to both the second direction and the third direction.

Optionally, the determination module 904 is further configured for:
determining a target time difference based on the first time point and the second time point;
determining, based on the target time difference and the angular velocity of the magnetic moment, an angle between the first probing light and the second probing light.

Optionally, the position of the first probing light relative to the atomic ensemble remains unchanged, and a position of the second probing light relative to the first probing light is variable.

The quantum measurement device provided in the above-mentioned embodiments of the present application can cause the magnetic moment of the atomic ensemble to perform uniform circular rotational motion, and determine the angle between the first probing light and the second probing light based on the first time point and the second time point detected by the first probing light and the second probing light.

It should be noted that the quantum measurement device provided in the embodiments of the present application can implement all of technical processes of the above-mentioned quantum measurement method and can achieve the same technical effect. To avoid repetition, it will not be repeated here.

Embodiments of the present application further provides a quantum measurement device, which includes an atom processing component, a first probe 2 and a second probe 3. The atom processing component includes a gas chamber 11, a heating structure 12 and a uniform rotation processing component. The atomic ensemble is arranged in the gas chamber 11, and the gas chamber 11 is filled with an inert gas; the gas chamber 11 is arranged in the heating structure 12; the uniform rotation processing component is arranged outside the heating structure 12, and is configured for applying a magnetic field and an optical field to the atomic ensemble to cause magnetic moment of the atomic ensemble to perform uniform circular rotational motion; the first probe 2 and the second probe 3 are arranged outside the heating structure 12, the light outlet of the first probe 2 faces the atomic ensemble, the light outlet of the second probe 3 faces the atomic ensemble, and the second probe 3 and the first probe 2 are arranged at intervals around the circumference of the atomic ensemble.

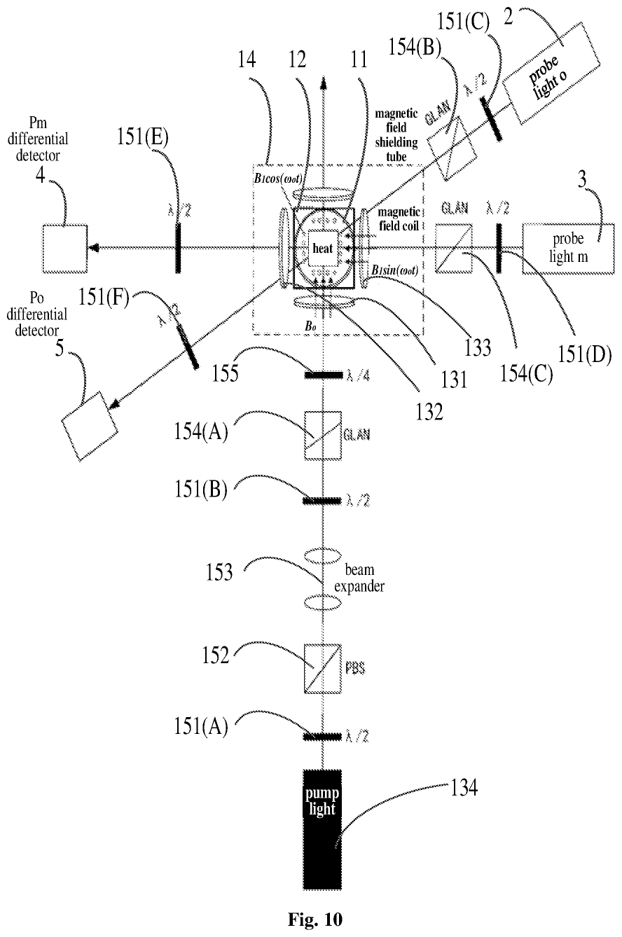

As shown in FIG. 10, the atomic ensemble moves in the gas chamber 11, which is made of glass, and is of cylindrical or spherical. The gas chamber 11 is filled with an inert gas as a working medium. The heating structure 12 covers the gas chamber 11, and the heating structure 12 is made of boron nitride material, which is non-magnetic and will not affect the motion of the atomic ensemble. The uniform rotation processing component is configured to cause the magnetic moment of the atomic ensemble to perform uniform circular rotational motion. The first probe 2 is configured to emit a first probing light, that is, the probe light o shown in FIG. 10, and the second probe 3 is configured to emit a second probing light, that is, the probe light m shown in FIG. 10. The first probe 2 and the second probe 3 emit the first probing light and the second probing light to the gas chamber 11 from different angles. When the first probing light detects the magnetic moment of the atomic ensemble, the optical signal will change, and the corresponding first time point is recorded. Similarly, the second time point when the second probing light detects the optical signal change of the magnetic moment of the atomic ensemble is recorded. According to the first time point, the second time point and the angular velocity of the magnetic moment of the atomic ensemble, the angular displacement of the atomic ensemble can be determined, thereby determining the angle between the first probe 2 and the second probe 3. The gas chamber 11, the heating structure 12, and the uniform rotation processing component ensure the high uniform speed of the atomic ensembles, thereby ensuring the accuracy of the quantum measurement device of the embodiments of the present application.

Optionally, the uniform rotation processing component includes a laser 134, a first magnetic field coil 131, a second magnetic field coil 132 and a third magnetic field coil 133; the laser 134, the first magnetic field coil 131, the second magnetic field coil 132 and the third magnetic field coil 133 are all arranged outside the heating structure 12, the coil plane of the first magnetic field coil 131 is perpendicular to the first direction and is arranged facing the atomic ensemble, the light outlet of the laser 134 is parallel to the first direction and is arranged facing the atomic ensemble, the coil plane of the second magnetic field coil 132 is perpendicular to the second direction and is arranged facing the atomic ensemble, the coil plane of the third magnetic field coil 133 is perpendicular to the third direction and is arranged facing the atomic ensemble; the second direction is perpendicular to the third direction, and the first direction is perpendicular to both the second direction and the third direction.

Referring to FIGS. 8 and 10. The first direction is the Z-axis direction shown in FIG. 8, the second direction is the Y-axis direction shown in FIG. 8, and the third direction is the X-axis direction shown in FIG. 8. The laser 134 is configured to emit the pump light. The first magnetic field coil 131 generates a static magnetic field along the first direction after being energized. The second magnetic field coil 132 generates a radio frequency magnetic field along the second direction after being energized. The third magnetic field coil 133 generates a radio frequency magnetic field along the third direction after being energized. Through the combined effect of the pump light, the static magnetic field in the first direction, the radio frequency magnetic field in the second direction, and the radio frequency magnetic field in the third direction, the magnetic moment of the atomic ensemble performs a uniform circular rotational motion with high uniformity around the first direction. The higher the uniformity, the more accurate the angular displacement of the atomic ensemble is measured. Therefore, the accuracy of the quantum measurement device of the embodiments of the present application is further improved by the uniform rotation processing component.

Optionally, the atom processing component also includes a magnetic field shielding tube 14, the gas chamber 11, the heating structure 12, the first magnetic field coil 131, the second magnetic field coil 132 and the third magnetic field coil 133, which are all located inside the magnetic field shielding tube 14. The laser 134, the first probe 2, and the second probe 3 are all located outside the magnetic field shielding tube 14.

As shown in FIG. 10, the gas chamber 11, the heating structure 12, the first magnetic field coil 131, the second magnetic field coil 132 and the third magnetic field coil 133 are all wrapped in a magnetic field shielding tube 14. The magnetic field shielding tube 14 is configured to shield the interference of the external magnetic field, thereby ensuring the uniformity of the magnetic moment motion of the atomic ensemble, thereby further ensuring the accuracy of the quantum measurement device of the embodiments of the present application.

Optionally, the atom processing component also includes a first optical processing component, a second optical processing component and a third optical processing component; the first optical processing component is arranged between the light outlet of the first probe 2 and the magnetic field shielding tube 14, and the first optical processing component is configured for adjusting the first probing light emitted by the first probe 2; the second optical processing component is arranged between the light outlet of the second probe 3 and the magnetic field shielding tube 14, and the second optical processing component is configured for adjusting the second probing light emitted by the second probe 3; the third optical processing component is arranged between the light outlet of the laser 134 and the magnetic field shielding tube 14, and the third optical processing component is configured for adjusting the pump light emitted by the laser 134.

As shown in FIG. 10, the third light processing member includes a first half wave plate 151 (A), a Polarization Beam Splitter (PBS) 152, a beam expander 153, a second half wave plate 151 (B), a Glan Taylor prism 154 (A), and a quarter wave plate 155, which are arranged in sequence along the direction from the pump light to the gas chamber 11. Optionally, the pump light is of a wavelength of 795 nm, which is linearly polarized with the atoms in the atomic ensemble. The pump light is circularly polarized light, and the quarter wave plate 155 converts the linearly polarized light into circularly polarized light. The first half wave plate 151 (A), the PBS 152, and the second half wave plate 151 (B) are configured to continuously adjust the light intensity of the pump light. The beam expander 153 enlarges a spot diameter of the pump light, so that the atoms can be fully polarized.

As shown in FIG. 10, the first optical processing component includes a third half wave plate 151 (C) and a Glan Taylor prism 154 (B) arranged in sequence along the direction from the probe light o to the gas chamber 11. Optionally, the probe light can be linearly polarized light with a wavelength of 780 nm. The Glan Taylor prism 154 (B) is configured to purify the polarization of the probe light. The third half wave plate 151 (C) and the Glan Taylor prism 154 (B) can continuously adjust the light intensity of the probe light. The second optical processing component includes a fourth half wave plate 151 (D) and a Glan Taylor prism 154 (C) arranged in sequence along the direction from the probe light m to the gas chamber 11, as shown in FIG. 10. Since the second optical processing component has the same structure and beneficial effects as the first optical processing component, it will not be repeated here.

In addition, in order to reduce the absorption of probe light by atoms at high temperatures, the frequency of the probe light needs to be far away from the atomic absorption region of 20 gigahertz (GHZ).

The quantum measurement device further includes a fifth half wave plate 151 (E), a sixth half wave plate 151 (F), a first differential detector 4 and a second differential detector 5. The first differential detector 4, that is, the differential detector Pₘ shown in FIG. 10, corresponds to the first probe 2. The gas chamber 11 is located between the first differential detector 4 and the first probe 2. The fifth half wave plate 151 (E) is arranged between the first differential detector 4 and the gas chamber 11. The second differential detector 5, that is, the differential detector P_{O} shown in FIG. 10, corresponds to the second probe 3. The gas chamber 11 is also located between the second differential detector 5 and the second probe 3. The sixth half wave plate 151 (F) is arranged between the second differential detector 5 and the gas chamber 11. The first differential detector 4 is configured to detect the optical signal of the first probe 2, and the second differential detector 5 is configured to detect the optical signal of the second probe 3. The fifth half wave plate 151 (E) and the sixth half wave plate 151 (F) can be configured to adjust the light intensity difference between the first probing light and the second probing light.

By setting the first light processing member, the second light processing member and the third light processing member, the uniform circular motion of the magnetic moment of the atomic ensemble and the accuracy of the detection results of the first probe 2 and the second probe 3 are further ensured, thereby improving the accuracy of the entire quantum measurement device.

Optionally, the first probe 2 is a fixed probe, and the second probe 3 is a movable probe.

As shown FIGS. 8 and 10, since the position of the movable probe is variable, the second probing light can be sent to the center point O at any position in the XY plane. It can be understood that the angular displacement between the first probe and the second probe at any position in the XY plane can be detected, thereby expanding the scope of application of the quantum measurement method of the embodiments of the present application.

It should be noted that, in the present application, the term “including”, “including” or any other variant thereof is intended to cover non-exclusive inclusion, so that a process, method, article or device including a series of elements includes not only those elements, but also includes other elements not explicitly listed, or also includes elements inherent to such process, method, article or device. In the absence of further restrictions, an element defined by the sentence “including one . . . ” does not exclude the presence of other identical elements in the process, method, article or device including the element. In addition, it should be pointed out that the scope of the method and device in the embodiments of the present application is not limited to performing functions in the order shown or discussed, and may also include performing functions in a substantially simultaneous manner or in reverse order according to the functions involved, for example, the described method may be performed in an order different from that described, and various steps may also be added, omitted, or combined. In addition, the features described with reference to certain examples may be combined in other examples.

The above are only specific implementations of the present application, but the protection scope of the present application is not limited thereto. Those of ordinary skill in the art can make changes or substitutions within the technical scope disclosed in the present application, which should be included in the protection scope of the present application. Therefore, the protection scope of the present application should be based on the protection scope of the claims.

1. A quantum measurement method, comprising:
processing an atomic ensemble to cause magnetic moment of the atomic ensemble to perform uniform circular rotational motion, and obtaining angular velocity of the magnetic moment of the atomic ensemble;
arranging a first probing light and a second probing light, wherein the first probing light and the second probing light are used to detect the magnetic moment of the atomic ensemble;
obtaining a first time point when the first probing light detects the magnetic moment of the atomic ensemble and a second time point when the second probing light detects the magnetic moment of the atomic ensemble;
determining an angle between the first probing light and the second probing light based on the first time point, the second time point, and the angular velocity of the magnetic moment of the atomic ensemble.

2. The quantum measurement method according to claim 1, wherein processing the atomic ensemble to cause the magnetic moment of the atomic ensemble to perform the uniform circular rotational motion comprises:
applying a static magnetic field to the atomic ensemble along a first direction;
applying pump light to the atomic ensemble along the first direction; and
applying a radio frequency magnetic field to the atomic ensemble along a second direction and a third direction, to cause the magnetic moment of the atomic ensemble to perform uniform circular rotational motion around the first direction, wherein the second direction is perpendicular to the third direction, and the first direction is perpendicular to both the second direction and the third direction.

3. The quantum measurement method according to claim 2, wherein determining the angle between the first probing light and the second probing light based on the first time point, the second time point, and the angular velocity of the magnetic moment comprises:
determining a target time difference based on the first time point and the second time point; and
determining an angle between the first probing light and the second probing light based on the target time difference and the angular velocity of the magnetic moment.

4. The quantum measurement method according to claim 1, wherein a position of the first probing light relative to the atomic ensemble is constant, and a position of the second probing light relative to the first probing light is variable.

5. A quantum measurement device, comprising:
an atom processing module, configured for processing an atomic ensemble to cause magnetic moment of the atomic ensemble to perform uniform circular rotational motion, and wherein angular velocity of the magnetic moment of the atomic ensemble is obtained;
a probe light arrangement module, configured for arranging a first probing light and a second probing light, wherein the first probing light and the second probing light are used to detect the magnetic moment of the atomic ensemble;
an obtaining module, configured for obtaining a first time point when the first probing light detects the magnetic moment of the atomic ensemble and a second time point when the second probing light detects the magnetic moment of the atomic ensemble; and
a determination module, configured for determining an angle between the first probing light and the second probing light based on the first time point, the second time point, and the angular velocity of the magnetic moment of the atomic ensemble.

6. A quantum measurement device, comprising an atom processing component, a first probe and a second probe, wherein:
the atom processing component comprises an gas chamber, a heating structure and a uniform rotation processing component;
an atomic ensemble is arranged in the gas chamber;
the gas chamber is filled with an inert gas; the gas chamber is arranged in the heating structure;
the uniform rotation processing component is arranged outside the heating structure, and is configured for applying a magnetic field and an optical field to the atomic ensemble to cause magnetic moment of the atomic ensemble to perform uniform circular rotational motion;
the first probe and the second probe are arranged outside the heating structure; and
a light outlet of the first probe faces the atomic ensemble, a light outlet of the second probe faces the atomic ensemble, and the second probe and the first probe are circumferentially arranged at an interval around the atomic ensemble.

7. The quantum measurement device according to claim 6, wherein:
the uniform rotation processing component comprises a laser, a first magnetic field coil, a second magnetic field coil and a third magnetic field coil;
the laser, the first magnetic field coil, the second magnetic field coil and the third magnetic field coil are all arranged outside the heating structure;
a coil plane of the first magnetic field coil is perpendicular to a first direction and arranged facing the atomic ensemble;
a light outlet of the laser is parallel to the first direction and arranged facing the atomic ensemble;
a coil plane of the second magnetic field coil is perpendicular to a second direction and arranged facing the atomic ensemble;
a coil plane of the third magnetic field coil is perpendicular to a third direction and is arranged facing the atomic ensemble;
the second direction is perpendicular to the third direction; and
the first direction is perpendicular to both the second direction and the third direction.

8. The quantum measurement device according to claim 7, wherein:
the atom processing component further comprises a magnetic field shielding tube;
the gas chamber, the heating structure, the first magnetic field coil, the second magnetic field coil and the third magnetic field coil are arranged inside the magnetic field shielding tube; and
the laser, the first probe and the second probe are arranged outside the magnetic field shielding tube.

9. The quantum measurement device according to claim 8, wherein:
the atom processing component further comprises a first light processing member, a second light processing member, and a third light processing member;
the first light processing member is arranged between the light outlet of the first probe and the magnetic field shielding tube, and is configured for adjusting a first probing light emitted by the first probe;
the second light processing member is arranged between the light outlet of the second probe and the magnetic field shielding tube, and is configured for adjusting a second probing light emitted by the second probe; and
the third light processing member is arranged between the light outlet of the laser and the magnetic field shielding tube, and is configured for adjusting pump light emitted by the laser.

10. The quantum measurement device according to claim 6, wherein the first probe is a fixed probe, and the second probe is a movable probe.

11. The quantum measurement method according to claim 2, wherein a position of the first probing light relative to the atomic ensemble is constant, and a position of the second probing light relative to the first probing light is variable.

12. The quantum measurement method according to claim 3, wherein a position of the first probing light relative to the atomic ensemble is constant, and a position of the second probing light relative to the first probing light is variable.

13. The quantum measurement device according to claim 7, wherein the first probe is a fixed probe, and the second probe is a movable probe.

14. The quantum measurement device according to claim 8, wherein the first probe is a fixed probe, and the second probe is a movable probe.

15. The quantum measurement device according to claim 9, wherein the first probe is a fixed probe, and the second probe is a movable probe.
